(19) United States
(12) Patent Application Publication
(10) Pub. No.: US 2024/0421057 A1
(43) Pub. Date: Dec. 19, 2024

(54) SMT PACKAGES AND SMT SUBSTRATES INCLUDED IN SMT PACKAGES

(71) Applicant: Samsung Electronics Co., Ltd., Suwon-si (KR)

(72) Inventors: Jinhyung Jung, Suwon-si (KR); Hyonchol Kim, Suwon-si (KR); Won Choi, Suwon-si (KR)

(21) Appl. No.: 18/591,183

(22) Filed: Feb. 29, 2024

(30) Foreign Application Priority Data
Jun. 13, 2023 (KR) 10-2023-0075290
Aug. 25, 2023 (KR) 10-2023-0111672

(51) Int. Cl. H01L 23/498

(52) U.S. Cl. CPC H01L 23/49822; H01L 23/49838

(57) ABSTRACT

A surface mount technology (SMT) package includes an SMT substrate including an interconnection layer, an insulating layer having an arrangement region for the interconnection layer, and a mask layer on an upper surface of the insulating layer, a component including an insulating body, and an external electrode having at least a portion on a surface of the insulating body opposing the SMT substrate, and a solder that electrically connects the interconnection layer and the external electrode to each other. The mask layer has an opening, and the SMT substrate further includes an insulating support that supports the external electrode in the opening such that the external electrode is spaced apart from the interconnection layer and the insulating layer.

### CROSS-REFERENCE TO RELATED APPLICATIONS

This application claims benefit of priority to Korean Patent Application No. 10-2023-0075290, filed on Jun. 13, 2023, and to Korean Patent Application No. 10-2023-0111672 filed on Aug. 25, 2023, in the Korean Intellectual Property Office, and the entire contents of the above-identified applications are incorporated by reference herein.

### BACKGROUND

The present disclosure relates to surface mount technology (SMT) packages and to SMT substrates included therein.

In general, a component may be mounted on a printed circuit board according to SMT, and the printed circuit board may transmit, to a semiconductor chip or electronic device printed circuit board (for example, a motherboard and a main board), inductance formed by the component or an inductance-based phenomenon (for example, resonance, passive filtering, or anti-static).

Recently, a printed circuit board and a component have been reduced in size. Accordingly, there has been an increasing level of difficulty in securing reliability of a package in which a printed circuit board and a component are integrated according to SMT.

### SUMMARY

The present inventive concepts provide surface mount technology (SMT) packages having improved reliability, and to SMT substrates included therein.

According to some aspects of the present inventive concepts, there is provided an SMT package including an SMT substrate including an interconnection layer, an insulating layer having an arrangement region for the interconnection layer, and a mask layer on an upper surface of the insulating layer, a component including an insulating body, and an external electrode having at least a portion on a surface of the insulating body opposing the SMT substrate, and a solder that electrically connects the interconnection layer and the external electrode to each other. The mask layer may have an opening. The SMT substrate may further include an insulating support that supports the external electrode in the opening such that the external electrode is spaced apart from the interconnection layer and the insulating layer.

According to some aspects of the present inventive concepts, there is provided an SMT substrate including an interconnection layer having first and second pad regions, an insulating layer having an arrangement region for the interconnection layer, a mask layer on an upper surface of the insulating layer and having an opening, a first insulating support in the opening such that a portion thereof overlaps the first pad region, and a second insulating support in the opening such that a portion thereof overlaps the second pad region.

According to some aspects of the present inventive concepts, there is provided an SMT substrate including an insulating layer, an interconnection layer embedded in the insulating layer, a mask layer on an upper surface of the insulating layer and having an opening, and first, second, third, and fourth insulating supports respectively in direct contact with the interconnection layer, the first, second, third, and fourth insulating supports respectively protruding from the mask layer toward the opening. The first, second, third and fourth insulating supports may be spaced apart from each other in the opening, and may be arranged two-dimensionally.

### BRIEF DESCRIPTION OF DRAWINGS

The above and other aspects, features, and advantages of the present inventive concepts will be more clearly understood from the following detailed description, taken in conjunction with the accompanying drawings, in which:

FIGS. 1A, 1B, 1C, 1D, 1E, and 1F are cross-sectional views illustrating an SMT package and an SMT substrate included therein according to an example embodiment of the present inventive concepts;

FIGS. 2A, 2B, and 2C are plan views illustrating arrangements of an interconnection layers and an insulating layer in an SMT package and an SMT substrate included therein according to an example embodiment of the present inventive concepts;

FIGS. 2D, 2E, 2F, and 2G are plan views illustrating arrangement of a mask layer and an insulating support in an SMT package and an SMT substrate included therein according to an example embodiment of the present inventive concepts;

FIGS. 3A, 3B, 3C, 3D, and 3E are cross-sectional views illustrating a method of manufacturing an SMT package and an SMT substrate included therein according to an example embodiment of the present inventive concepts;

FIGS. 4A, 4B, 4C, and 4D are enlarged cross-sectional views illustrating an insulating support and a surrounding structure thereof of an SMT package and an SMT substrate included therein according to an example embodiment of the present inventive concepts;

FIGS. 5A, 5B, and 5C are cross-sectional views illustrating an SMT package and an SMT substrate included therein according to an example embodiment of the present inventive concepts; and

FIGS. 6A, 6B, and 6C are perspective views illustrating a component that may be included in an SMT package according to an example embodiment of the present inventive concepts.

### DETAILED DESCRIPTION

The detailed description of the present inventive concepts refers to the accompanying drawings which, by way of example, illustrate specific embodiments in which the present inventive concepts may be practiced. These embodiments are described in sufficient detail to enable one skilled in the art to practice the present inventive concepts. It should be understood that the various embodiments of the present inventive concepts may be different from each other but are not necessarily mutually exclusive. For example, aspects of an example embodiment having specific shapes, structures, and characteristics described herein may be implemented in another embodiment without departing from the spirit and scope of the present inventive concepts. Additionally, it should be understood that the location or arrangement of individual components within each disclosed embodiment may be changed without departing from the spirit and scope of the present inventive concepts. Accordingly, the detailed description set forth below is not intended to be taken in a limiting sense, and the scope of the present inventive concepts is limited only by the appended claims, with all equivalents as claimed by those claims. Like reference numbers in the drawings indicate the same or similar function throughout the various examples of embodiments.

Hereinafter, some examples of embodiments of the present inventive concepts will be described in detail with reference to the accompanying drawings such that those skilled in the art may practice the present inventive concepts.

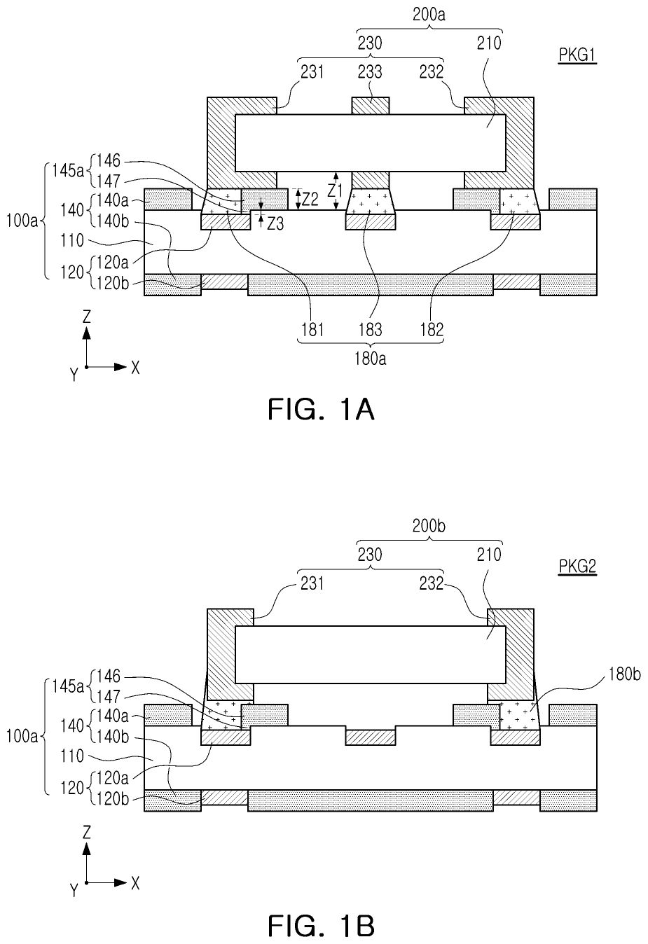

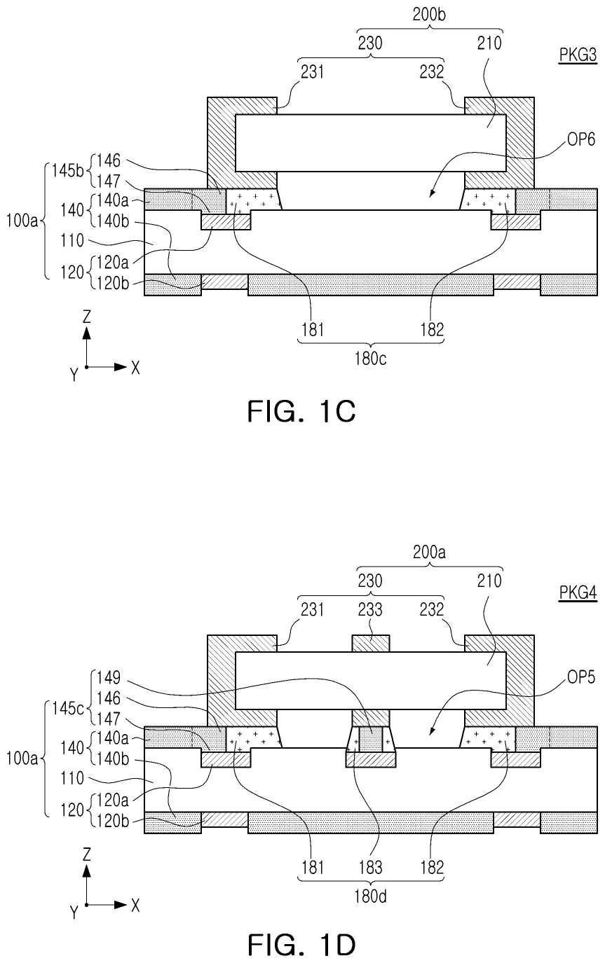

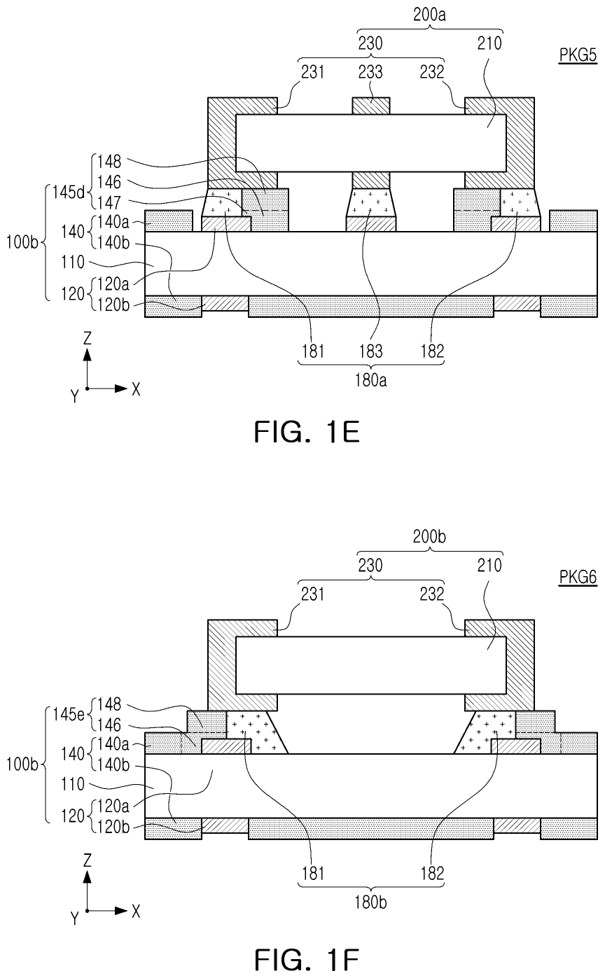

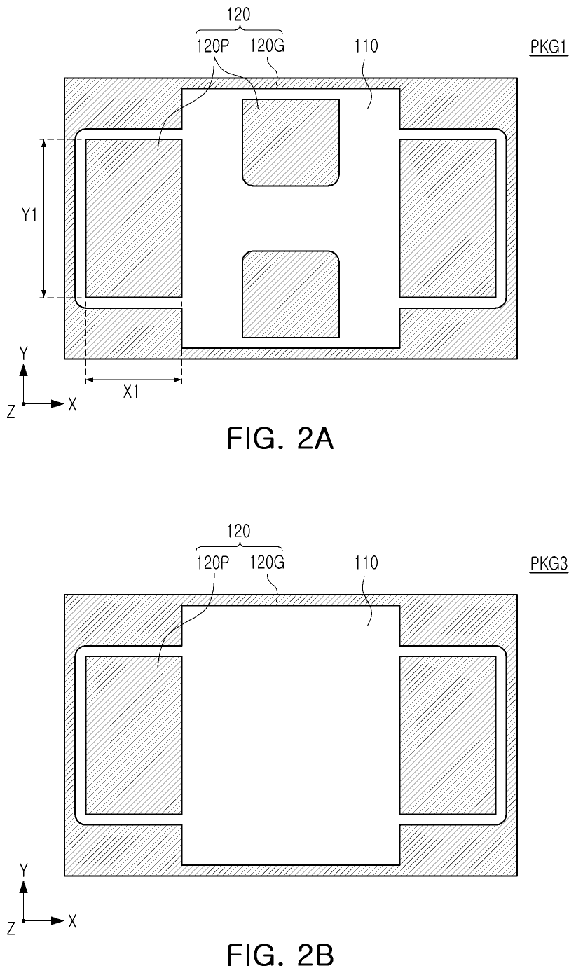

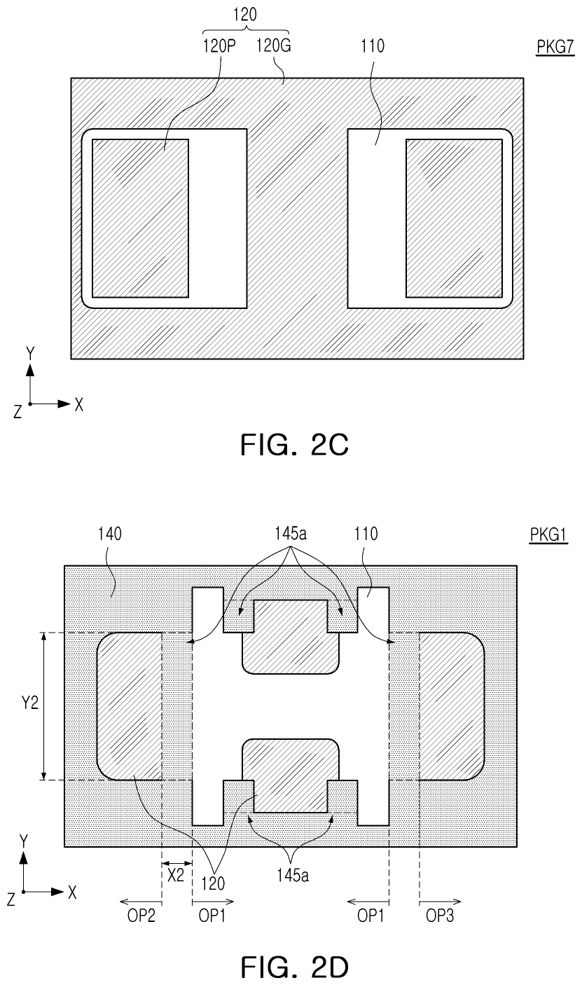

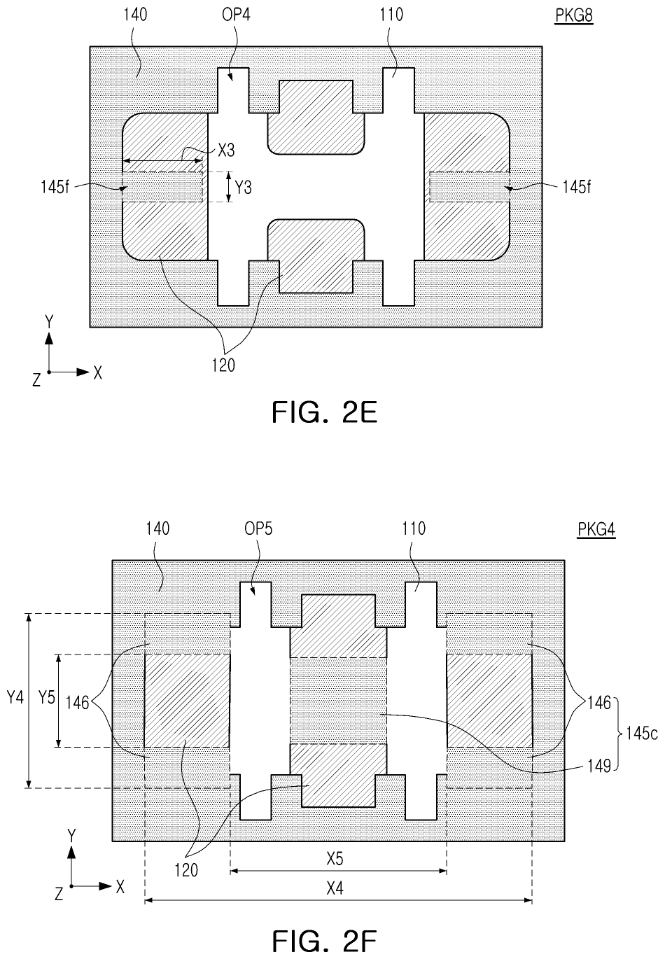

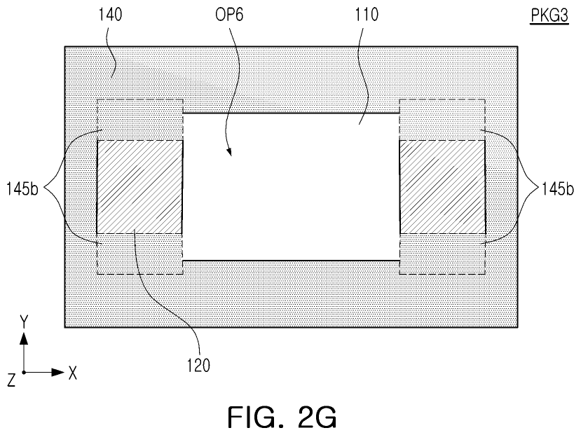

Referring to FIGS. 1A to 2G, SMT packages PKG1, PKG2, PKG3, PKG4, PKG5, PKG6, PKG7, and PKG8 according to some example embodiments of the present inventive concepts may include SMT substrates 100a and 100b, components 200a and 200b, and solders 180a, 180b, 180c, and 180d.

The SMT substrates 100a and 100b may include an interconnection layer 120, an insulating layer 110, a mask layer 140, and insulating supports 145a, 145b, 145c, 145d, 145c, and/or 145f. The SMT substrate 100a may be an embedded trace substrate (ETS), and the SMT substrate 100b may be a protruded trace substrate (PTS), but the present disclosure is not limited thereto.

The interconnection layer 120 may include at least one of a plurality of interconnection layers 120a and 120b, and the plurality of interconnection layers 120a and 120b may be on an upper portion and a lower portion of the insulating layer 110, respectively. The SMT substrate 100a may have a structure in which the interconnection layer 120a is embedded in the insulating layer 110, and the SMT substrate 100b may have a structure in which the interconnection layer 120a is on an upper surface of the insulating layer 120 and/or protruding therefrom. The insulating layer 110 may provide or have an arrangement region for the interconnection layer 120a. The interconnection layer 120 may include copper (Cu) or a copper alloy, but the present disclosure is not limited thereto. For example, the interconnection layer 120 may include aluminum (Al), silver (Ag), tin (Sn), gold (Au), nickel (Ni), lead (Pb), titanium (Ti), or alloys thereof.

The insulating layer 110 may include prepreg, but the present disclosure is not limited thereto. For example, the insulating layer 110 may include at least one of a photosensitive insulating material such as photoimageable dielectric (PID) resin, a build-up film such as an Ajinomoto build-up film (ABF), a thermosetting resin such as an epoxy resin, or a thermoplastic resin such as polyimide, a resin mixed with an inorganic filler, flame retardant (FR-4), and bismaleimide triazine (BT).

For example, the interconnection layer 120 may have at least one of a pad region 120P and a ground region 120G. The pad region 120P may be connected to an interconnection of the interconnection layer 120, and the interconnection may extend in a horizontal direction (X-direction and/or Y-direction) and/or a vertical direction (Z-direction). Accordingly, the interconnection layer 120 may provide an electrical connection path with respect to the components 200a and 200b and the solders 180a, 180b, 180c and 180d electrically connected to an upper surface of the pad region 120P. The ground region 120G may surround the pad region 120P, and may be spaced apart from the pad region 120P. The ground region 120G may shield external electromagnetic noise to the interconnection, serve as a heat dissipation path to the outside of the SMT substrates 100a and 100b, and improve impedance stability of the interconnection.

The mask layer 140 may include at least one of a plurality of mask layers 140a and 140b, and the plurality of mask layers 140a and 140b may cover upper and lower surfaces of the insulating layer 110, respectively. An insulating material included in the mask layer 140 may be different from an insulating material included in the insulating layer 110. The mask layer 140 may include, but is not limited to, a material that may be contained in a solder resist layer of a printed circuit board. For example, the mask layer 140 may include at least one of a material that may be contained in a dry film resist, a photosensitive insulating material such as a PID resin, a build-up film such as an ABF, a thermosetting resin such as an epoxy resin, a thermoplastic resin such as polyimide, a resin mixed with an inorganic filler, FR-4, and BT.

The mask layer 140 may include openings OP1, OP2, OP3, OP4, OP5, and OP6, and a size and shape of each of the openings OP1, OP2, OP3, OP4, OP5, and OP6 may be determined using surface mount technology (SMT), but the present disclosure is not limited thereto. For example, the size and shape of each of the openings OP1, OP2, OP3, OP4, OP5, and OP6 may be determined based on a size and shape of each of the components 200a and 200b. As compared to multiple openings of a general ball grid array (BGA) substrate, the openings OP1, OP2, OP3, OP4, OP5, and OP6 may have a larger size, and may have a shape closer to a polygonal shape (for example, rectangular shape).

The components 200a and 200b may overlap the openings OP1, OP2, OP3, OP4, OP5, and OP6 in a Z-direction, and may include an insulating body 210 and an external electrode 230.

The insulating body 210 may form impedance (for example, capacitance, inductance, or resistance) or an impedance-based phenomenon (for example, resonance, passive filtering, anti-static). For example, when the insulating body 210 forms capacitance, the insulating body 210 may include a plurality of dielectric layers including a ferroelectric such as barium titanate (BaTiO₃), and may include a plurality of internal electrodes between the plurality of dielectric layers. The plurality of internal electrodes may be connected to the external electrode 230 to transmit the capacitance to the outside of the components 200ₐ and 200_{b}. For example, when the insulating body 210 forms inductance, the insulating body 210 may include not only an insulating material but also magnetic powder particles (for example, metal powder particles or ferrite powder particles) for increasing permeability, and may include a coil connected to the external electrode 230. For example, when the insulating body 210 forms an impedance-based phenomenon, the insulating body 210 may be a composite component having a structure for forming capacitance and a structure for forming impedance together.

At least a portion of the external electrode 230 may be on a surface (for example, lower surface) of the insulating body 210 opposing the SMT substrates 100a and 100b. The external electrode 230 may be on a surface of the insulating body 210, and may transmit, to the SMT substrates 100a and 100b, an impedance formed by the insulating body 210 or an impedance-based phenomenon. To this end, the external electrode 230 may be electrically connected to the interconnection layer 120 via the solders 180a, 180b, 180c, and 180d.

The external electrode 230 of the component 200a may include first, second, and third external electrodes 231, 232, and 233 spaced apart from each other, and the external electrode 230 of the component 200b may include first and second external electrodes 231 and 232 spaced apart from each other. For example, the external electrode 230 may include copper (Cu), aluminum (Al), silver (Ag), tin (Sn), gold (Au), nickel (Ni), lead (Pb), titanium (Ti), or alloys thereof, and may include a resin including a plurality of metal particles.

The solders 180a, 180b, 180c, and 180d may electrically connect the interconnection layer 120 and the external electrode 230 to each other. The first, second, and third solders 181, 182, and 183 of the solders 180a, 180b, 180c, and 180d may be connected to the first, second, and third external electrodes 231, 232, and 233, respectively. For example, the solders 180a, 180b, 180c, and 180d may contain lead (Pb), tin (Sn), or an alloy (Sn—Ag—Cu) containing tin (Sn), and thus may have a melting point lower than a melting point of the interconnection layer 120. At a temperature higher than the melting point, the solders 180a, 180b, 180c, and 180d may be flexibly connected between an upper surface of the interconnection layer 120a and the external electrode 230 by a reflow process or a thermal compression bonding (TCB) process in a flowable state. Thereafter, the temperature may be lowered, and the solders 180a, 180b, 180c, and 180d may be stuck in a state of being connected to the upper surface of the interconnection layer 120a and the external electrode 230. Accordingly, the components 200a and 200b may be mounted on the SMT substrates 100a and 100b.

The SMT substrates 100a and 100b and the components 200a and 200b may be gradually reduced in size. Accordingly, a thickness of the external electrode 230 may be gradually reduced, and an upper surface of the interconnection layer 120a may gradually move downwardly. For example, as the interconnection layer 120a is embedded in the insulating layer 110, the upper surface of the interconnection layer 120a may move downwardly. The frequency of application of such an ETS structure may gradually increase with a reduction in size of the SMT substrates 100a and 100b.

As the SMT substrates 100a and 100b and/or components 200a and 200b are reduced in size, the SMT substrates 100a and 100b and/or components 200a and 200b may have increased performance relative to the size thereof. However, a distance Z1 between the insulating body 210 of the SMT substrates 100a and 100b and the components 200a and 200b may decrease. As the distance Z1 decreases, a level of difficulty of securing reliability between the SMT substrates 100a and 100b and the components 200a and 200b may increase. For example, as the distance Z1 decreases, it may be difficult to secure reliability of removing foreign substances between the SMT substrates 100a and 100b and the components 200a and 200b due to cleaning after the reflow process. For example, as the distance Z1 decreases, it may be difficult to secure reliability (for example, performance of suppressing formation of voids) of filling an encapsulant such as an epoxy molding compound (EMC) between the SMT substrates 100a and 100b and the components 200a and 200b. For example, as the distance Z1 decreases, it may be difficult to secure reliability of preventing an electrical short circuit from occurring in the solders 180a, 180b, 180c, and 180d.

The insulating supports 145a, 145b, 145c, 145d, 145e, and 145f may support the external electrode 230 in the openings OP1, OP2, OP3, OP4, OP5, and OP6 such that the external electrode 230 is spaced apart from the interconnection layer 120 and the insulating layer 110. Accordingly, even when the SMT substrates 100a and 100b and/or components 200a and 200b are reduced in size, the distance Z1 between the insulating body 210 of the SMT substrates 100a and 100b and the components 200a and 200b may efficiently increase. In addition, the solders 180a, 180b, 180c, and 180d may be more stably formed

The insulating supports 145a, 145b, 145c, 145d, 145c, and 145f may include first insulating supports (e.g., left sides of 145a, 145b, 145c, 145d, 145e, and 145f) and second insulating supports (e.g., right sides of 145a, 145b, 145c, 145d, 145e, and 145f), and may be spaced apart from one opening OP1, OP2, OP3, OP4, OP5, or OP6 with central portions of the openings OP1, OP2, OP3, OP4, OP5, OP6 interposed therebetween. A portion of the first insulating supports (e.g., left sides of 145a, 145b, 145c, 145d, 145e, and 145f) may overlap a first pad region (e.g., left side of 120P), and a portion of the second insulating supports (e.g., right sides of 145a, 145b, 145c, 145d, 145c, and 145f) may overlap a second pad region (e.g., right side of 120P).

Accordingly, the insulating supports 145a, 145b, 145c, 145d, 145e, and 145f may support more efficiently the external electrode 230 of the components 200a and 200b having a reduced size, and a distance between the insulating body 210 of the SMT substrates 100a and 100band the components 200a and 200b may increase more effectively. In addition, even when the insulating supports 145a, 145b, 145c, 145d, 145e, and 145f have a relatively small size in a horizontal direction, a relatively large overlapping region in a Z-direction between the insulating supports 145a, 145b, 145c, 145d, 145e, and 145f and the external electrode 230 may be secured, and an electrical connection path between the external electrode 230 and the interconnection layer 120a may also be secured more stably.

For example, the external electrode 230 may include a first electrode having at least a portion on a portion (for example, left region) of a surface (for example, lower surface) of the insulating body 210 opposing the SMT substrates 100a and 100b, and a second external electrode 232 having at least a portion on another region (for example, right region) of the surface (for example, lower surface) of the insulating body 210 opposing the SMT substrates 100a and 100b). The first insulating supports (left sides of 145a, 145b, 145c, 145d, 145e, and 145f) may support a first external electrode 231 in the openings OP1, OP2, OP3, OP4, OP5, and OP6, and the second insulating supports (right sides of 145a, 145b, 145c, 145d, 145e, and 145f) may support a second external electrode 232 in the openings OP1, OP2, OP3, OP4, OP5, and OP6.

For example, a portion of the insulating supports 145a, 145b, 145c, 145d, 145e, and 145f may be on an upper surface of the insulating layer 110, and another portion of the insulating supports 145a, 145b, 145c, 145d, 145e, and 145f may be on an upper surface of the interconnection layer 120a. Accordingly, the insulating supports 145a, 145b, 145c, 145d, 145e, and 145f may support more stably the external electrode 230.

Referring to FIGS. 1A to 1D, the upper surface of the interconnection layer 120a may be in direct contact with the solders 180a, 180b, 180c, and 180d, and the interconnection layer 120a may be embedded in the insulating layer 110. Here, an average distance (Z2+Z3) between a lower surface of the external electrode 230 and the upper surface of the interconnection layer 120a may be greater than an average thickness (Z2) of the mask layer. Such a structure may be a structure in which the insulating supports 145a, 145b, and 145c support the external electrode 230.

The insulating supports 145a, 145b, and 145c may include an insulating material the same as an insulating material included in the mask layer 140. Depending on the interpretation, the insulating supports 145a, 145b, and 145c may be considered as being included in the mask layer 140. For example, the insulating supports 145a, 145b, and 145c may be formed together when an opening of the mask layer 140 is formed. When the insulating supports 145a, 145b, and 145c and the mask layer 140 are in direct contact with each other, an interface between the insulating supports 145a, 145b, and 145c and the mask layer 140 may not be observed.

The distance (Z2+Z3) between the lower surface of the external electrode 230 and the upper surface of the interconnection layer 120a may be greater than the thickness (Z2) of the mask layer, such that the upper surface of the interconnection layer 120a may be positioned on a level lower than that of the upper surface of the insulating layer 110. A reference direction for measuring a height (level) may be a direction (Z-direction) in which the SMT substrates 100a and 100b and the components 200a and 200b oppose each other. When the insulating supports 145a, 145b, and 145c are in direct contact with the mask layer 140, a portion 146 of the insulating supports 145a, 145b, and 145c may be positioned on a level higher than that of the upper surface of the insulating layer 110, and another portion 147 of the insulating supports 145a, 145b, and 145c may be positioned on a level lower than that of the upper surface of the insulating layer 110. Accordingly, the insulating supports 145a, 145b, and 145c may more stably support the external electrode 230. For example, Z2 may be 10 μm or more and 30 μm or less, and Z3 may be more than 0 μm and 5 μm or less, but the present disclosure is not limited thereto.

Referring to FIGS. 1E and IF, the interconnection layer 120a may be on the upper surface of the insulating layer 110, and the insulating supports 145d and 145e may upwardly protrude toward the external electrode 230. A portion 146 of the insulating supports 145d and 145e may overlap the insulating layer 110 in the Z-direction, another portion 147 of the insulating supports 145d and 145e may overlap the interconnection layer 120a in the Z-direction, and an upper protrusion 148 of the insulating supports 145d and 145e may be positioned on a level higher than that of an upper surface of the mask layer 140. Accordingly, upper surfaces of first insulating supports (left sides of 145d and 145e) may be positioned on a level higher than that of the upper surface of the mask layer 140, and upper surfaces of second insulating supports (right sides of 145d and 145e) may be positioned on a level higher than that of the upper surface of the mask layer 140.

Depending on the design, the insulating supports 145d and 145e may include an insulating material different from the insulating material included in the mask layer 140. For example, the insulating supports 145d and 145e may include an insulating material that may be included in the insulating layer 110, and may include an insulating material having a rigidity greater than that of the mask layer 140. Insulating materials having different rigidities (or Young's modulus) may be a type of different insulating materials. For example, the portion 146 and the other portion 147 of the insulating supports 145d and 145e may include an insulating material the same as the insulating material included in the mask layer 140, and the upper protrusion 148 of the insulating supports 145d and 145e may include an insulating material different from the insulating material included in the mask layer 140.

Referring to FIGS. 2B, 2F, and 2G, the SMT packages PKG3 and PKG4 according to some example embodiments of the present inventive concepts may include a first insulating support (e.g., upper left side of 146 in FIG. 2F and 2G), a second insulating support (e.g., upper right side of 146 in FIGS. 2F and 2G), a third insulating support (e.g., lower left side of 146 in FIGS. 2F and 2G), and a fourth insulating support (e.g., lower right side of 146 in FIGS. 2F and 2G), spaced apart from each other with a central portion of the openings OP5 and OP6 interposed therebetween. Referring to FIGS. IC and ID, first and third insulating supports (e.g., left sides of 145b and 145c) may support the first external electrode 231, and second and fourth insulating supports (e.g., right sides of 145b and 145c) may support the second external electrode 232.

A portion of the first insulating support (e.g., upper left side of 146 in FIGS. 2F and 2G) may overlap the first pad region (e.g., left side of 120P), and another portion of the first insulating support (e.g., upper left side of 146 in FIGS. 2F and 2G) may overlap the insulating layer 110. A portion of the second insulating support (e.g., upper right side of 146 in FIGS. 2F and 2G) may overlap the second pad region (e.g., right side of 120P), and another portion of the second insulating support (e.g., upper right side of 146 in FIGS. 2F and 2G) may overlap the insulating layer 110. A portion of the third insulating support (e.g., lower left side of 146 in FIGS. 2F and 2G) may overlap the first pad region (e.g., left side of 120P), and another portion of the third insulating support (e.g., lower left side of 146 in FIGS. 2F and 2G) may overlap the insulating layer 110. A portion of the fourth insulating support (e.g., lower right side of 146 in FIGS. 2F and 2G) may overlap the second pad region (e.g., right side of 120P), and another portion of the fourth insulating support (e.g., lower right side of 146 in FIGS. 2F and 2G) may overlap the insulating layer 110.

Accordingly, the first, second, third and fourth insulating supports 145b and 145c may support more efficiently the external electrode 230 of the components 200a and 200b having a reduced size, and a distance between the insulating body 210 of the SMT substrates 100a and 100b and the components 200a and 200b may increase more effectively. In addition, even when the insulating supports 145a, 145b, 145c, 145d, 145e, and 145f have a relatively small size in a horizontal direction, a relatively large overlapping region in a Z-direction between the first, second, third and fourth insulating supports 145b and 145c and the external electrode 230 may be secured, and an electrical connection path between the external electrode 230 and the interconnection layer 120a may also be stably secured.

For example, the first insulating support (e.g., upper left side of 146 in FIGS. 2F and 2G), the second insulating support (e.g., upper right side of 146 in FIGS. 2F and 2G), the third insulating support (146 in FIGS. 2F and 2G), and the fourth insulating support (e.g., lower right side of 146 in FIGS. 2F and 2G) may be in direct contact with the mask layer 140, may protrude from the mask layer 140 toward central portions of the openings OP5 and OP6, and may be arranged two-dimensionally within the openings OP5 and OP6. In some embodiments, the first, second, third and fourth insulating supports 145b and 145c, protruding from the mask layer 140 toward the openings OP5 and OP6, may be implemented in the form of irregularities on boundary lines of the openings OP5 and OP6, and may be different from a smooth shape such as a circle or polygon.

Referring to FIGS. ID and 2F, the external electrode 230 of the SMT package PKG4 according to some example embodiments of the present disclosure may further include a third external electrode 233 having at least a portion on a surface (for example, lower surface) of the insulating body 210 opposing the SMT substrate 100a, and spaced apart from the first and second external electrodes 231 and 232. The SMT package PKG4 may further include a fifth insulating support 149 supporting the third external electrode 233 in the opening OP5. The fifth insulating support 149 may be spaced apart from the first, second, third, and fourth insulating supports 146. Accordingly, the SMT package PKG4 may support the component 200a more efficiently, such that each of the first, second, and third solders 181, 182, and 183 of the solder 180d may have a more stable size and/or shape, and the possibility of an electrical short circuit occurring between the first, second, and third solders 181, 182, and 183 may be further suppressed. That is, despite a reduction of a space between the SMT package PKG4 and the component 200a due to the third external electrode 233, reliability between the SMT package PKG4 and the component 200a may be further improved.

For example, a portion of the fifth insulating support 149 may overlap a third pad region (e.g., central portion of 120P) in FIG. 2A, and another portion of the fifth insulating support 149 may overlap the insulating layer 110. The fifth insulating support 149 may be spaced apart from the first, second, third and fourth insulating supports 146, and may be surrounded by the first, second, third and fourth insulating supports 146. Referring to FIG. 2G, the fifth insulating support may be omitted.

Referring to FIG. 2A, the number of third pad regions (e.g., central portion of 120P) of an interconnection layer may be plural. Referring to FIG. 2B, the third pad region of the interconnection layer may be omitted. Referring to FIG. 2C, a first pad region (e.g., left side of 120P) and a second pad region (e.g., right side of 120P) of the interconnection layer may be isolated from each other by the ground region 120G.

Referring to FIGS. 1A and 2D, the insulating support 145a may be in the form of partition, dividing an opening into a plurality of openings OP1, OP2, and OP3. Accordingly, each of the first, second, and third solders 181, 182, and 183 of the solder 180a may have a more stable size and/or shape, and the possibility of an electrical short circuit occurring between the first, second, and third solders 181, 182, and 183 may be further suppressed. For example, a length in an X-direction (X2) of the insulating support 145a that is in the form of a partition may be longer than a length in a Y-direction length (Y2) of the insulating support 145a that is in the form of a partition, and may be shorter than a length in the X-direction (X1) of the pad region 120P in FIG. 2A. For example, the length in the Y-direction (Y2) of the insulating support 145a that is in the form of a partition may be longer than a length in the Y-direction (Y1) of the pad region 120P in FIG. 2A. Depending on the design, the insulating support 145a may protrude from the mask layer 140 in the Y-direction, but may have a relatively short protrusion so as not to be divided into a plurality of openings.

Referring to FIG. 2E, each of the first and second insulating supports 145f may protrude from the mask layer 140 toward each other in the X-direction. For example, a length in the X-direction (X3) of a protrusion of each of the first and second insulating supports 145f may be longer than a length in the Y-direction (Y3) of the protrusion of each of the first and second insulating supports 145f.

Referring to FIG. 2F, a shortest separation distance (Y5) between first and second insulating supports (e.g., upper side of 146) and third and fourth insulating supports (e.g., lower side of 146) may be shorter than the length in the Y-direction (Y1) of the pad region 120P in FIG. 2A. A longest separation distance (Y4) between the first and second insulating supports (upper side of 146) and the third and fourth insulating supports (lower side of 146) may be longer than the length in the Y-direction (Y1) of the pad region 120P in FIG. 2A. A shortest separation distance (X5) between the first and third insulating supports (e.g., left side of 146) and the second and fourth insulating supports (e.g., right side of 146) may be longer than the shortest separation distance (Y5) between the first and second insulating supports (e.g., upper side of 146) and the third and fourth insulating supports (e.g., lower side of 146). A longest separation distance (X4) between the first and third insulating supports (e.g., left side of 146) and the second and fourth insulating supports (e.g., right side of 146) may be longer than the longest separation distance (Y4) between the first and second insulating supports (e.g., upper side of 146) and the third and fourth insulating supports (e.g., lower side of 146).

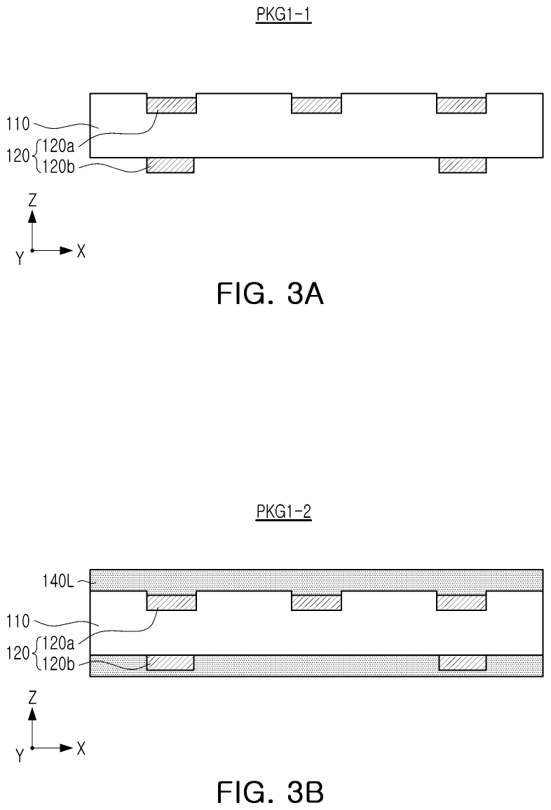

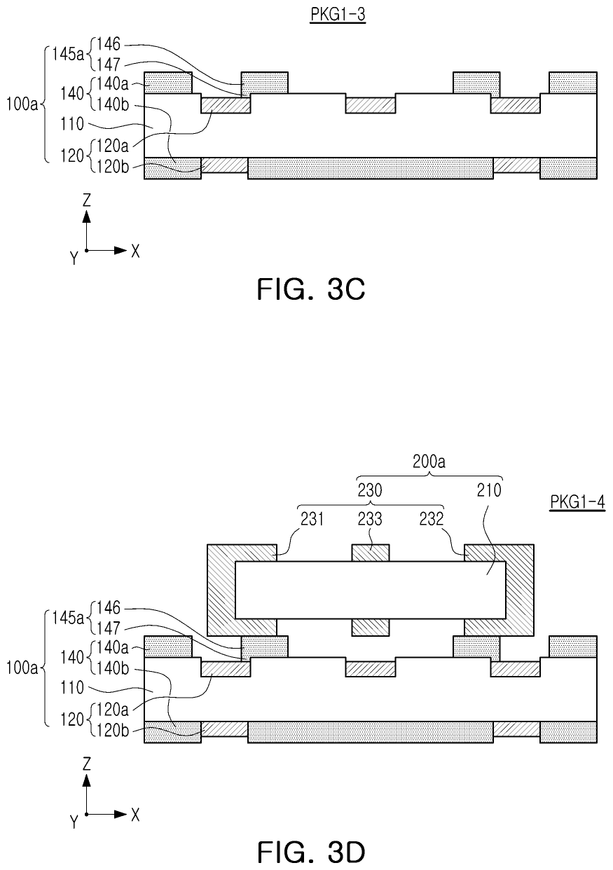

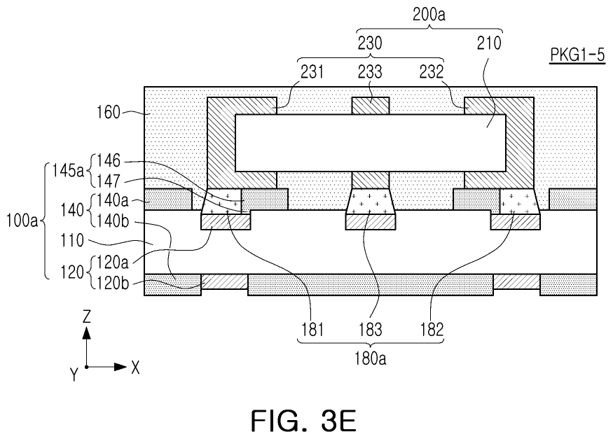

FIGS. 3A to 3E illustrate a method of manufacturing the SMT package PKG1 in FIGS. 1A, 2A, and 2D. Referring to FIG. 3A, a first state PKG1-1 of the SMT package may have a structure in which an interconnection layer 120 is on upper and lower portions of an insulating layer 110. For example, a horizontal shape of the interconnection layer 120 may be implemented using photolithography.

Thereafter, in FIG. 3B, a second state PKG1-2 of the SMT package may have a structure in which a mask layer 140L covers upper and lower surfaces of the insulating layer 110. Thereafter, in FIG. 3C, a third state PKG1-3 of the SMT package may have a structure in which an insulating support 145a is formed together with formation of an opening of a mask layer 140.

Thereafter, in FIG. 3D, a fourth state PKG1-4 of the SMT package may have a structure in which a component 200a is on an upper surface of an SMT substrate 100a. Thereafter, in FIG. 3E, a fifth state PKG1-5 of the SMT package may have a structure in which a solder 180a connects an external electrode 230 of the component 200a and an interconnection layer 120a to each other. Depending on the design, an encapsulant 160 may be filled in an empty space of an upper side of the SMT substrate 100a. For example, the encapsulant 160 may be an epoxy molding compound (EMC).

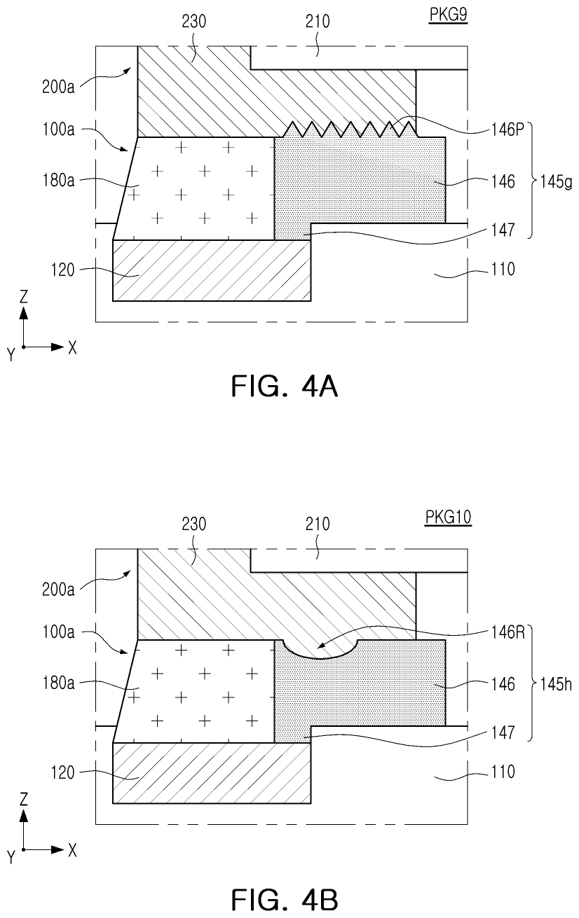

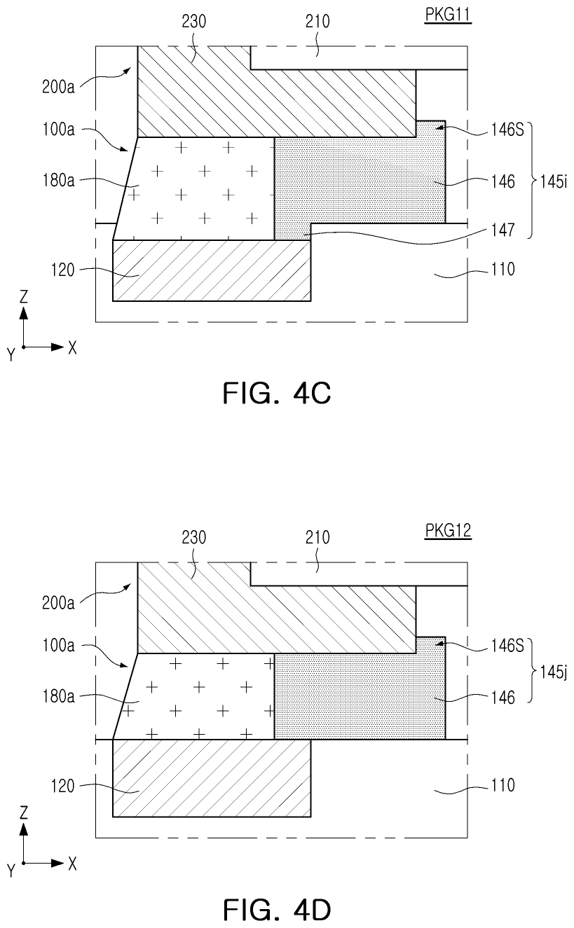

Referring to FIGS. 4A to 4D, insulating supports 145g, 145h, 145i, and 145j may be in direct contact with an external electrode 230. Referring to FIG. 4D, depending on the design, an upper surface of an interconnection layer 120 and an upper surface of an insulating layer 110 may substantially form one plane.

Referring to FIGS. 4A and 4B, a roughness of upper surfaces 146P and 146R of the insulating supports 145g and 145h may be greater than a roughness of lower surfaces of the insulating supports 145g and 145h. For example, the upper surface 146P of the insulating support 145g may have a sawtooth shape, and the upper surface 146R of the insulating support 145h may have a concave shape. For example, the roughness of the upper surfaces 146P and 146R of the insulating supports 145g and 145h may be implemented using a plasma process or a fine particle collision process, but the present disclosure is not limited thereto.

Referring to FIG. 4C, due to reaction of the insulating support 145i supporting the external electrode 230, a portion 146S of the insulating support 145i may be dented by the external electrode 230. Accordingly, the portion 146S of the insulating support 145i may be positioned on a level higher than that of a lower surface of the external electrode 230.

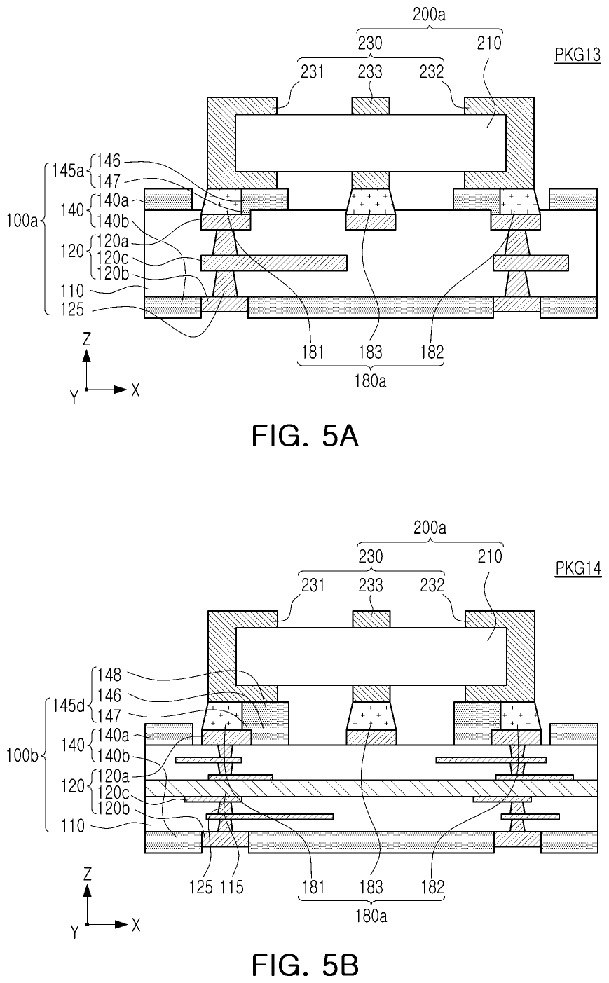

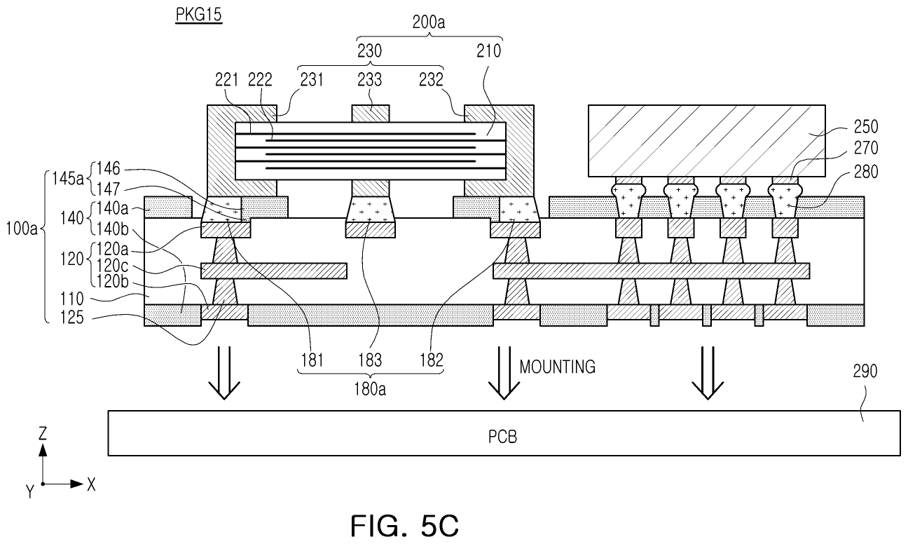

Referring to FIG. 5A, the number of interconnection layers 120 (for example, three or more) of an SMT package PKG13 according to some example embodiments of the present disclosure may be greater than the number of interconnection layers 120 (one or two) in FIGS. 1A to 1F. A plurality of interconnection layers 120a, 120b, and 120c may be stacked in a Z-direction with a portion of an insulating layer 110 interposed therebetween, and may be electrically connected to each other in the Z-direction by interconnection vias 125. For example, the interconnection vias 125 may have a cylindrical shape, having an inclined side surface having a width decreasing upwardly, and may have a conformal via structure partially filled with a conductive material (for example, copper (Cu), aluminum (Al), silver (Ag), tin (Sn), gold (Au), nickel (Ni), lead (Pb), titanium (Ti), or alloys thereof) or a filled via structure fully filled with the conductive material. At least a portion 120cof the plurality of interconnection layers 120a, 120b, and 120cmay be in the form of an interconnection extending in a horizontal direction according to patterning.

Referring to FIG. 5B, an SMT substrate 100b of an SMT package PKG14 according to some example embodiments of the present disclosure may include a core insulating layer 115. The core insulating layer 115 may include an insulating material that may be included in an insulating layer 110, and may have a rigidity stronger than that of the insulating layer 110. For example, the core insulating layer 115 may be formed based on a copper clad laminate (CCL), but the present disclosure is not limited thereto.

Referring to FIG. 5C, an SMT package PKG15 according to some example embodiments of the present disclosure may further include a semiconductor chip 250 mounted on an SMT substrate 100a. For example, the semiconductor chip 250 may include chip pads 270 on a lower surface of the semiconductor chip 250, and may be electrically connected to the interconnection layer 120 via chip pads 270 and bumps 280. The bumps 280 may be in multiple through-holes of the mask layer 140. The bumps 280 may include a conductive material having a low melting point, such as a material that may be included in a solder 180a.

For example, the semiconductor chip 250 may be a microprocessor, such as a central processing unit (CPU), graphic processing unit (GPU), field programmable gate array (FPGA), application processor (AP), digital signal processor, cryptographic processor, controller, or application specific integrated circuit (ASIC).

Depending on the design, the semiconductor chip 250 may be mounted on the SMT substrate 100b in FIGS. 1E and IF. Here, the semiconductor chip 250 may be a volatile memory such as dynamic random access memory (DRAM), static random access memory (SRAM), or a non-volatile memory such as flash memory. The SMT substrate 100b in FIGS. 1E and IF may be larger than the SMT substrate 100a in FIGS. 1A to 1D, and may be more efficient in implementing a high bandwidth memory (HBM).

The SMT board 100a may be mounted downwardly on an electronic device printed circuit board 290. That is, the SMT substrate 100a and the SMT package PKG15 may be within an electronic device. For example, the electronic device may include a smartphone, a personal digital assistant, a digital video camera, a digital still camera, a network system, a computer, a monitor, a tablet, a laptop, a netbook, a television, a video game, a smart watch, an automobile, or the like. The electronic device printed circuit board 290 may be a mother board or a main board.

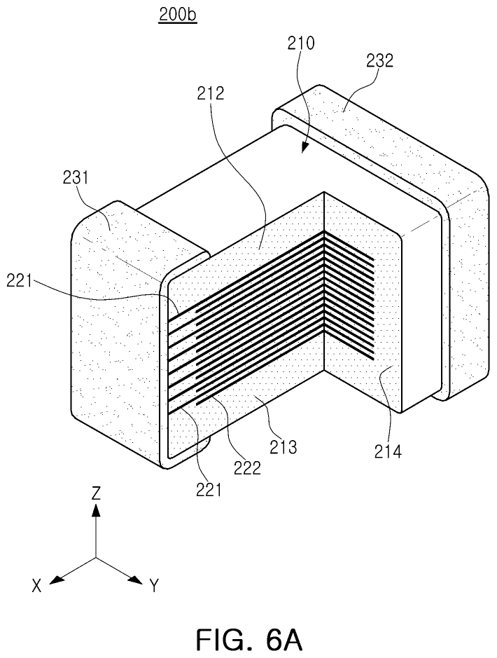

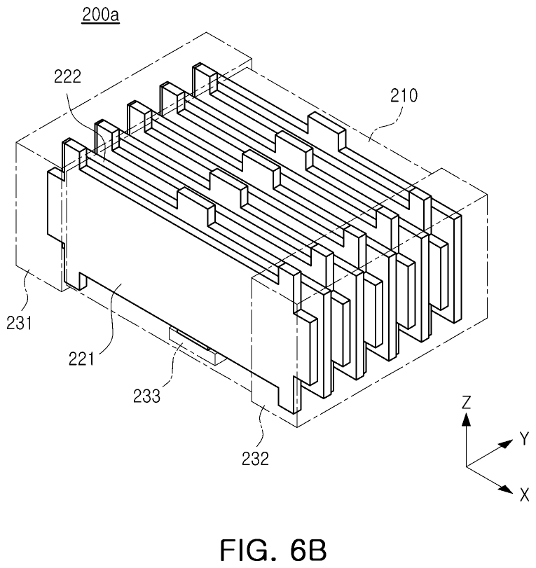

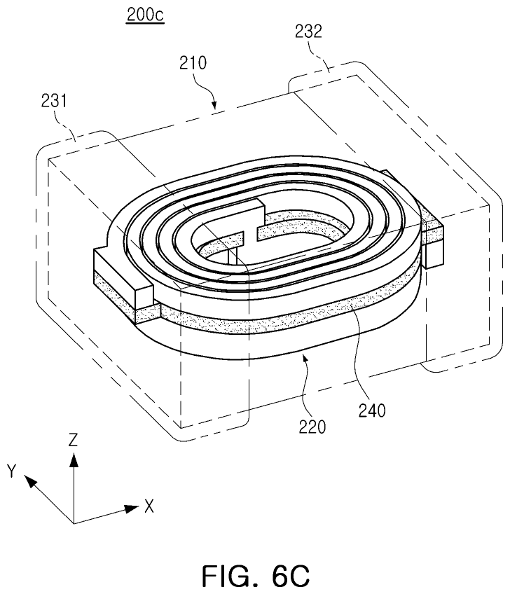

Referring to FIGS. 5C, 6A, and 6B, the components 200a and 200b may have a structure in which a plurality of first internal electrodes 221 and a plurality of second internal electrodes 222 are alternately within the insulating body 210. Referring to FIG. 6A, a first external electrode 231 of the component 200b may be connected to the plurality of first internal electrodes 221, and a second external electrode 232 of the component 200b may be connected to the plurality of second internal electrodes 222. Referring to FIG. 6B, the first and second external electrodes 231 and 232 of the component 200a may be connected to the plurality of first internal electrodes 221, and a third external electrode 233 of the component 200a may be connected to the plurality of second internal electrodes 222. Accordingly, the components 200a and 200b may efficiently form capacitance.

Depending on the design, the component 200b may include a side margin portion 214 covering the plurality of first internal electrodes 221 and the plurality of second internal electrodes 222 in a Y-direction, and cover portions 212 and 213 covering the plurality of first internal electrodes 221 and the plurality of second internal electrodes 222 in a Z-direction. Each of a plurality of dielectric layers of the body 210 may be between the plurality of first internal electrodes 221 and the plurality of second internal electrodes 222, and may include a ferroelectric material such as barium titanate (BaTiO₃). The side margin portion 214 and the cover portions 212 and 213 may also include a ferroelectric material such as barium titanate (BaTiO₃), but the present disclosure is not limited thereto. For example, the side margin portion 214 and the cover portions 212 and 213 may include an insulating material having a relatively low dielectric constant, as compared to the ferroelectric material, and higher performance for protecting the insulating body 210.

Referring to FIG. 6C, a component 200c may include a coil 220 within the insulating body 210. One end of the coil 220 may be connected to a first external electrode 231, and the other end of the coil 220 may be connected to a second external electrode 232. Accordingly, the component 200c may efficiently form inductance.

For example, the coil 220 may be on upper and lower surfaces of an insulating support layer 240, and may include a conductive material (for example, copper (Cu), aluminum (Al), silver (Ag), tin (Sn), Gold (Au), nickel (Ni), lead (Pb), titanium (Ti), or alloys thereof). The insulating support layer 240 may include an insulating material that may be included in an insulating layer of an SMT substrate. The insulating body 210 may include not only the insulating material but also magnetic powder particles (for example, metal powder particles and ferrite powder particles) for increasing permeability, and thus may have a permeability higher than that of the insulating support layer 240. FIG. 6C illustrates a thin film-type inductor, but the present disclosure is not limited thereto. For example, the component 200c may be implemented as a wire-wound inductor or a stacked inductor, or as a bead or common mode filter.

An SMT package and an SMT substrate included therein according to some example embodiments of the present inventive concepts may secure more efficiently a distance between a component and the SMT substrate, thereby improving reliability between the component and the SMT substrate.

While some examples of embodiments have been shown and described above, it will be apparent to those skilled in the art that modifications and variations could be made without departing from the scope of the present inventive concepts as defined by the appended claims.

Listing of the claims:

1. A surface mount technology (SMT) package comprising:
an SMT substrate including an interconnection layer, an insulating layer having an arrangement region for the interconnection layer, and a mask layer on an upper surface of the insulating layer;
a component including an insulating body, and an external electrode having at least a portion on a surface of the insulating body opposing the SMT substrate; and
a solder that electrically connects the interconnection layer and the external electrode to each other,
wherein the mask layer has an opening, and
wherein the SMT substrate further includes an insulating support that supports the external electrode in the opening such that the external electrode is spaced apart from the interconnection layer and the insulating layer.

2. The SMT package of claim 1, wherein:
a first portion of the insulating support is on the upper surface of the insulating layer, and
a second portion of the insulating support is on an upper surface of the interconnection layer.

3. The SMT package of claim 1, wherein an upper surface of the interconnection layer is in direct contact with the solder and in direct contact with the insulating support.

4. The SMT package of claim 3, wherein the upper surface of the interconnection layer is positioned on a level lower than that of the upper surface of the insulating layer.

5. The SMT package of claim 1, wherein:
an upper surface of the interconnection layer is in direct contact with the solder, and the interconnection layer is embedded in the insulating layer.

6. The SMT package of claim 5, wherein a distance between a lower surface of the external electrode and the upper surface of the interconnection layer is greater than a thickness of the mask layer.

7. The SMT package of claim 1, wherein the insulating support includes an insulating material that is a same material as an insulating material included in the mask layer.

8. The SMT package of claim 1, wherein the insulating support is in direct contact with the mask layer.

9-12. (canceled)

13. The SMT package of claim 1, wherein the insulating support protrudes toward the external electrode.

14. The SMT package of claim 13, wherein the insulating support includes an insulating material that is different from an insulating material included in the mask layer.

15. The SMT package of claim 1, wherein:
the external electrode includes a first external electrode having at least a portion on a portion of the surface of the insulating body opposing the SMT substrate, and a second external electrode having at least a portion on another portion of the surface of the insulating body opposing the SMT substrate,
the insulating support includes a first insulating support that supports the first external electrode in the opening, and a second insulating support that supports the second external electrode in the opening,
the first and second external electrodes are spaced apart from each other, and the first and second insulating supports are spaced apart from each other such that a portion of the opening is interposed therebetween. 16-18. (Canceled)

19. The SMT package of claim 1, further comprising:
a semiconductor chip mounted on the SMT substrate.

20. A surface mount technology (SMT) substrate comprising:
an interconnection layer having first and second pad regions;
an insulating layer having an arrangement region for the interconnection layer;
a mask layer on an upper surface of the insulating layer and having an opening;
a first insulating support in the opening such that a portion of the first insulating support overlaps the first pad region; and
a second insulating support in the opening such that a portion of the second insulating support overlaps the second pad region.

21. The SMT substrate of claim 20, further comprising:
a third insulating support arranged in the opening such that a portion of the third insulating support overlaps the first pad region; and
a fourth insulating support arranged in the opening such that a portion of the fourth insulating support overlaps the second pad region, wherein the first, second, third and fourth insulating supports are spaced apart from each other such that a portion of the opening is interposed therebetween.

22. The SMT substrate of claim 21, further comprising:
a fifth insulating support arranged in the opening such that a portion of the fifth insulating support overlaps a third pad region of the interconnection layer,
wherein the fifth insulating support is spaced apart from the first, second, third and fourth insulating supports, and is surrounded by the first, second, third and fourth insulating supports.

23. The SMT substrate of claim 21, wherein each of the first, second, third and fourth insulating supports protrudes from the mask layer toward the opening.

24. The SMT substrate of claim 20, wherein each of the first and second insulating supports protrudes toward each other from the mask layer.

25. The SMT substrate of claim 20, wherein each of the first and second insulating supports comprises a partition that divides the opening.

26-30. (canceled)

31. A surface mount technology (SMT) substrate comprising:
an insulating layer;
an interconnection layer embedded in the insulating layer;
a mask layer on an upper surface of the insulating layer and having an opening; and
first, second, third, and fourth insulating supports respectively in direct contact with the interconnection layer, the first, second, third, and fourth insulating supports respectively protruding from the mask layer toward the opening,
wherein the first, second, third and fourth insulating supports are spaced apart from each other in the opening, and are arranged two-dimensionally.

32. The SMT substrate of claim 31, wherein:
each of the first, second, third and fourth insulating supports includes an insulating material that is a same material as an insulating material included in the mask layer, and
an upper surface of the interconnection layer is positioned on a level lower than that of the upper surface of the insulating layer.
